(19) United States
(12) Patent Application Publication
(10) Pub. No.: US 2007/0016834 A1
(43) Pub. Date: Jan. 18, 2007

(54) Reducing Power Dissipation During Sequential Scan Tests

(75) Inventors: Sankar Prasad DEBNATH, Bangalore (IN); Anand BHAT, Bangalore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/160,857

(22) Filed: Jul. 13, 2005

(51) Int. Cl. G01R 31/28

(52) U.S. Cl. 714/726

(57) ABSTRACT

A scan cell which provides two data outputs, one of use in scan mode and another in functional mode. The functional mode output is connected to functional portions, and transitions on the functional mode output are avoided by using an isolation circuit. As a result, the inputs in functional portions may not toggle during scan operation, thereby reducing the power dissipation in test mode of sequential tests.

### BACKGROUND OF THE INVENTION

1. Field of the Invention

The present invention relates to the field of design of integrated circuit and more specifically to a method and apparatus for reducing power dissipation while testing integrated circuits using sequential scan techniques.

2. Related Art

Sequential scan techniques are often used to test integrated circuits, and characterized by two modes of operation—functional mode and test mode. In functional mode, elements (both combinatorial and sequential) in an integrated circuit are connected according to a desired design and to provide a desired utility for which the integrated circuit is primarily designed.

On the other hand, in test mode, various sequential elements (such as flip-flops) of an integrated circuit are connected in a sequence (i.e., the output of one element is connected as an input to the next element) referred to as a “scan chain”. The remaining circuit portions, not part of the scan chain and generally containing several combinatorial logic elements, are conveniently referred to as functional circuit portions.

In a typical sequential scan test scenario, a number of bits in a particular pattern of zeros and ones (“scan vector”) are sequentially (one bit at every clock cycle) loaded (scanned-in) into a scan chain through the first element of the scan chain. The number of bits contained in the scan vector generally equals the number of memory elements in a corresponding scan chain.

Once a scan chain is loaded with a scan vector, the functional circuit portions (generally the combinatorial logic) of the integrated circuit are evaluated based on the scanned in bits. The flip-flops (contained in the scan cell) are designed to latch the results of the evaluation, and the bits latched in the scan chain are sequentially scanned out (scan-out) (one bit at every clock cycle) through the last scan cell in the scan chain. The received scan out is compared with an expected scan out corresponding to the scan vector to determine the various faults within the integrated circuit. The scan-in and scan-out operations are generally referred to as scan operations.

From the above, it may be appreciated that each sequential element (of a scan chain) may need to receive input from two paths, one in functional mode and another in scan mode. Such dual connectivity is generally obtained by using a scan cell containing a multiplexer along with a sequential element. The multiplexer selectively connects either a functional mode input or a scan mode input to the input of the sequential element depending on whether the integrated circuit is operating in functional mode or test mode.

One general requirement in performing sequential tests is reducing power dissipation during test time. Reduction of power dissipation is often of concern, for example, since substantially more power dissipation can occur in test mode compared to functional mode, and integrated circuits may be designed with a power dissipation specification corresponding to only the functional mode.

What is therefore needed is reducing power dissipation while testing the integrated circuits using sequential scan techniques.

### BRIEF DESCRIPTION OF THE DRAWINGS

The present invention will be described with reference to the following accompanying drawings, which are described briefly below.

FIG. 1 is a block diagram illustrating the details of an example prior integrated circuit, which can be improved using various aspects of the present invention can be implemented.

FIG. 2 is a timing diagram illustrating the toggings (which cause unneeded power dissipation) in a prior integrated circuit.

FIG. 3 is a block diagram illustrating the structure of a scan cell in an embodiment of the present invention.

FIG. 4 is a block diagram illustrating the manner in which power dissipation can be reduced according to an aspect of the present invention.

FIG. 5 is a timing diagram illustrating the power reduction attained in an embodiment.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

1. Overview

An aspect of the present invention reduces power consumption during sequential scan testing of integrated circuits. The power reduction is achieved by isolating the functional circuit portion from the output of sequential elements during scan (in and out) operations of the integrated circuit. As a result, toggling of gates within the functional portion is avoided during scan operations, thereby reducing the overall power dissipation of integrated circuits.

In one embodiment, the isolation is achieved by using an AND gate, which blocks the output of the corresponding sequential element from being provided to the functional portion during the scan operation. The AND gate passes the output of the sequential element to the functional portion during evaluation mode as well as normal operation (functional mode).

A scan cell provided according to an aspect of the present invention accordingly contains two data outputs, with a first output for the functional portions and the second (other) output for the next sequential element(s) in the scan chain. The AND gate noted above is provide associated with the first output such that the output of the sequential element is provided to the functional portions only during functional mode, thereby preventing transitions to the functional portions.

Due to such prevention, switching of gates/transistors is avoided in the functional portions during scan operations, thereby reducing power dissipation during sequential scan tests.

Various aspects of the present invention will be clearer in comparison to a prior integrated circuit in which at least some features of the present invention are not implemented. Accordingly, the details of such a prior integrated circuit are described below first.

2. Example Prior Integrated Circuit

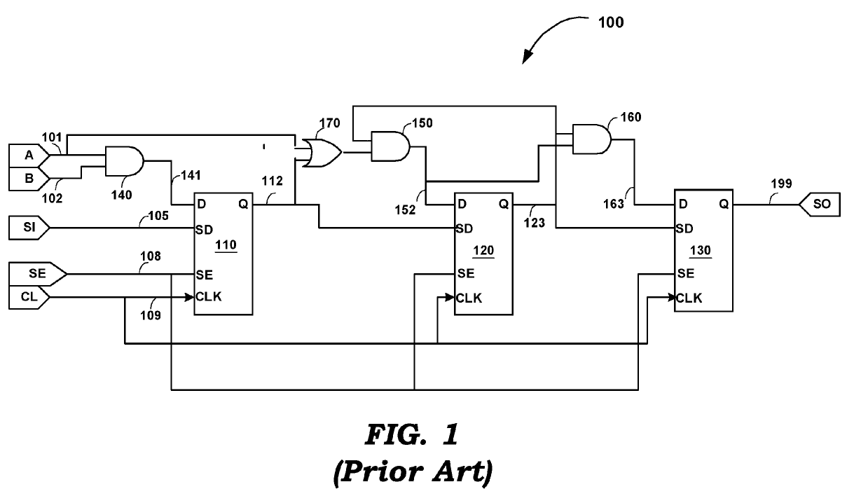

FIG. 1 is a circuit diagram illustrating an example portion of a prior integrated circuit designed to support sequential scan tests. Integrated circuit 100 is shown containing scan cells 110, 120 and 130, AND gates 140, 150 and 160, and OR gate 170. Each component is described below in further detail.

Each scan cell 110, 120, and 130 is shown with four input terminals D, SD, SE, CLK and one output terminal Q. Terminal D is designed to receive data in functional mode according to functional mode circuit design. Terminal SD is designed to receive data in test (scan) mode from a preceding scan cell (not shown) in the scan chain. Terminal SE receives a logic high to indicate scan operation logic low to indicate a functional mode of operation. Terminal CLK receives a clock signal for timing the latch operations of the scan cells.

Scan cells 110, 120, 130 are provided for connection as a scan chain, with scan cell 110 as first element and scan cell 130 as last element in the scan chain. Accordingly, scan cell 110 is shown receiving a functional data on path 141 (terminal D) from the output of AND gate 140 and scan data on path 105 from an external interface SI (scan in) on terminal SD. Data output (Q) of scan cell 110 is provided to OR gate 170 and also to SD terminal of scan cell 120 on path 112.

Similarly, scan cell 120 is shown receiving functional data on path 152 (from AND gate 150) and scan data on path 112 (from preceding scan cell 110). The output of scan cell 120 is provided to AND gates 150/160 and SD input of scan cell 130 on path 123. Scan cell 130 is shown receiving functional data on path 163 (from AND gate 160) and scan data on path 123 (from preceding scan cell 120). The output of scan cell 130 is provided to external interface SO (scan out) on path 199.

Each or a combination of connected combinatorial elements (AND gates 140, 150 and 160 and OR gate 170) represents a functional circuit portion connected to provide a desired functionality.

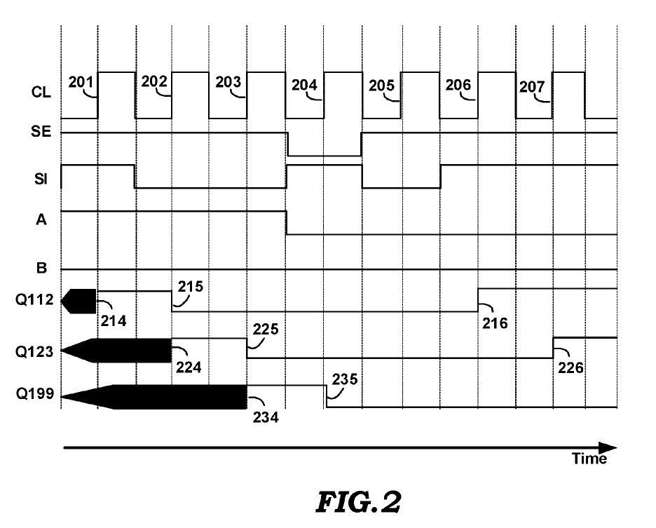

A source of power dissipation during sequential scan testing is the toggling of inputs to the gates (which may cause transistors forming gates to switch, dissipating energy) as illustrated with reference to the timing diagram of FIG. 2. The timing diagram contains signals clock (CL), scan enable (SE), scan data (SI), functional data A and B (provided as inputs to AND gate 140), output on path 112 (Q112), output on path 123 (Q123) and output on path 199 (Q199).

SE signal is shown logic high at rising edges 201-203 and 205-207 (representing the aggregate scan duration). Thus the duration 201-203 corresponds to a scan-in operation (of bits 100 on IS), 204 corresponds to evaluation, and duration 205-207 corresponds to scan-out operation. The dark areas (in durations up to 201, up to 202 and 203 respectively for Q112, Q123, and Q199) represent that the logic levels are unknown (depending on previous bits scanned).

As can be readily observed, the logic 0 scanned in at time point 202 following a 1 at time point 201 causes respective transitions on Q112 (at time point 215), on Q123 (at time point 225) and on Q199 (at time point 235). Similarly, during the scan out operation, transitions are observed at time points 216 (on Q112), 226 (on Q123). Such transitions cause a toggle at the inputs of combinational logics (140, 150, 160 and 170).

The aggregate number of such toggles (in the entire integrated circuit) per clock cycle is generally more than when the integrated circuits operate in functional mode. Accordingly, the power dissipation is typically more during sequential scan operation in the circuit of FIG. 1 per clock cycle.

The problem may be alleviated by using a higher clock period (lower frequency for scan operation). However, the lower speed can lead to correspondingly more test time, and thus to the overall cost of testing integrated circuits. This might be particularly problematic as the complexity of the integrated circuits increase (due to longer scan chains as well as more gates in combinatorial logic). Various aspect of present invention overcome at least some of the limitations described above.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

3. Novel Scan Cell

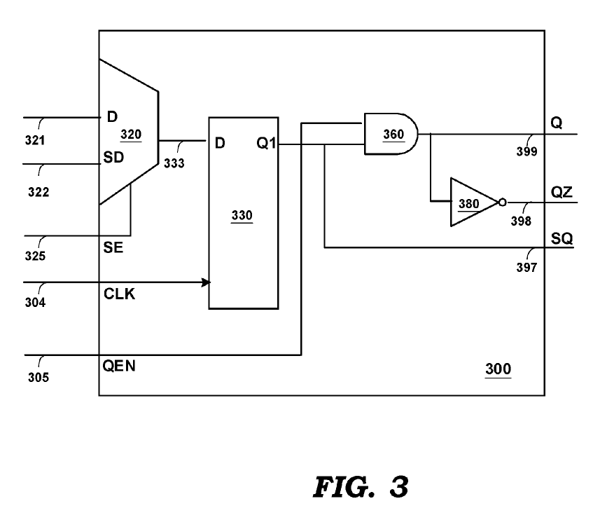

FIG. 3 is a circuit diagram illustrating an example scan cell provided according to an aspect of present invention. Scan cell 300 is shown containing flip-flop 330 (an example of a sequential element), multiplexer (MUX) 320, AND gate 360 and NOT gate (inverter) 380. Scan cell 300 is shown receiving five inputs D, SD, SE, CLK, QEN and providing two outputs (Q and SQ).

D, SD, SE and CLK signals are similar to those described above with respect to FIG. 1, and the description is not repeated in the interest of conciseness. QEN is a control signal which indicates the specific durations in which the output of flip-flop 330 should not be provided on Q output, and can be derived as an inverted signal of SE.

Broadly, the output Q provides functional data to be routed (connected) to functional circuit portion and SQ provides a scan data to be routed to scan chain path in an integrated circuit. By isolating the transitions at the output of flip-flop 330 from Q output during scan mode, the toggling of functional circuit portion (thereby power dissipation) while performing scan operation may be avoided. Each component is described below in further detail.

Input terminals 321 and 322 of MUX 320 receive functional data and scan data respectively. Terminal 321 receiving functional data is represented as D, and terminal 322 receiving scan data is represented as SD. Select terminal 325 of MUX 320 receives scan enable (SE) signal. Hence, one logic level (logic high) of the scan enable connects data (scan data) on terminal 322 to input of the flip-flop 330, and another logic level (logic low) connects data (functional data) on terminal 321 to input of flip-flop 330.

Flip-flop 330 receives output of MUX 320 on terminal D (data terminal) and a clock signal on CLK (304) terminal. Flip-flop 330 latches the received data on to the output terminal (Q1) on occurrence of a clock signal (rising/falling edge). The output (Q1) from flip-flop 330 is provided on path 397 as scan data output terminal (SQ). It should be appreciated that other types of sequential elements can be used in place of flip-flop 330, as suited in specific designs.

AND gate 360 receives the output of flip-flop (Q1) on one of the terminals and a control signal (QEN) (305) on other terminal. The output of AND gate 360 is provided as functional data output terminal (Q). An inverted out put of (Q) is provided on path 398 (QZ) using a NOT gate 380 for design convenience. Accordingly, when the control signal (QEN) is at logic low, AND gate 360 prevents the output of flip-flop 330 from being propagated to functional path 399, thereby avoiding the unneeded togglings in functional portion.

Thus, AND gate 360 represents an example circuit which isolates the output of flip-flop 330 from the functional portion connected to the Q output of scan cell 300. However, various alternative embodiments of such isolation circuits will be apparent to one skilled in the relevant arts by reading the disclosure provided herein. Such alternative embodiments are contemplated to be within the scope and spirit of the present invention.

The embodiments thus provided can be used in various integrated circuits. For illustration, the manner in which the circuit of FIG. 1 can be modified using the circuit of FIG. 3, is described below.

4. Design of Integrated circuits With Reduced Power Consumption

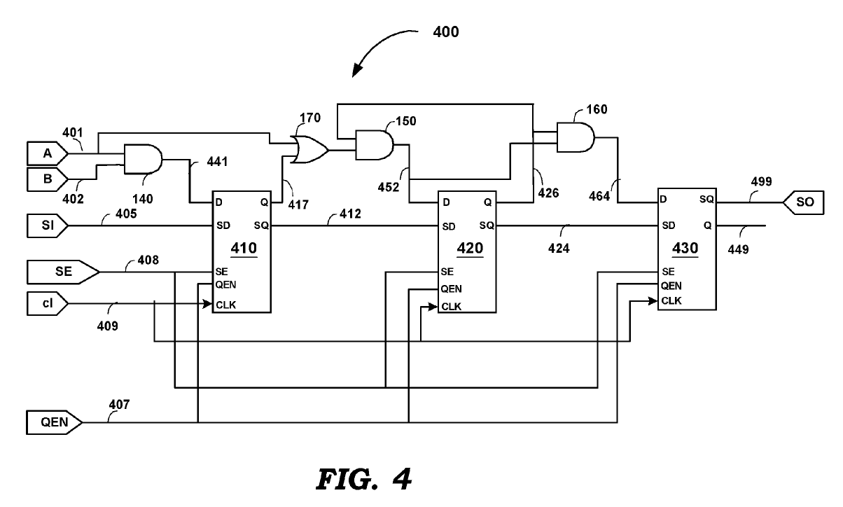

FIG. 4 is a block diagram illustrating the manner in which integrated circuits can be designed according to various aspects of the present invention. In particular, as noted above, FIG. 4 illustrates the manner in which integrated circuit 100 can be modified using scan cells designed according to FIG. 3.

For conciseness, the same circuit elements of FIG. 1 are repeated in FIG. 4, except that scan cells 110, 120 and 130 are respectively replaced by scan cells 410, 420 and 430 (implemented according to the approached described with respect to FIG. 3). The common elements are not described again, and the differences are described in further detail below.

As can be readily observed, the Q output of scan cell 420 is connected as the respective inputs of AND gates 150 and 160 (functional portion(s)). Assuming that QEN is maintained low in scan mode, Q output would be maintained at logic low during the entire scan operations. As a result, the undesired toggling of the inputs of AND gates 150 and 160 would be avoided. However, Q output would be connected to AND gates 150 and 160 when QEN is at logic high (in functional mode), as desired.

On the other hand, SQ output of scan cell 420 is shown connecting to the SD terminal of scan cell 430. By observing FIG. 3, it may be appreciated that when the SE signal indicates scan mode of operation (logic high in this embodiment), scan cell 430 forms a subsequent cell in the scan chain. In such a situation, the output available on SQ of scan cell 420 would be propagated to the SD input of scan cell 430, as desired. The operation of scan cells 410 and 430 can also be described similarly.

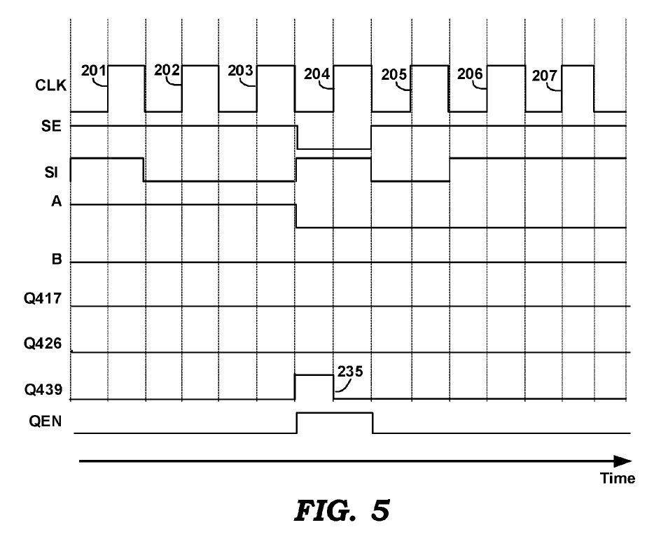

The operation of the circuit of FIG. 4 is illustrated in further detail with respect to the timing diagram of FIG. 5. For comparison, the same scan sequence (SI), clock signal (CL), A, B, and scan enable (SE) signals as in FIG. 2, are used. The Q outputs on paths 417, 426 and 439 (shown as Q417, Q426 and Q439 in FIG. 5) is maintained at logic 0 in all durations (201-203 and 205-207) in scan mode, thereby avoiding all the transitions on the corresponding signals explained above with respect to FIG. 2. The power dissipation of integrated circuit 400 is reduced (in comparison to integrated circuit 100) as a result.

It should be appreciated that the AND gate provided in each scan cell operates as a desired isolation circuit. However, isolation circuits can be provided external to the scan cells, at points (typically before high fan out points) external to the scan cells are well.

5. Conclusion

While various embodiments of the present invention have been described above, it should be understood that they have been presented by way of example only, and not limitation. Thus, the breadth and scope of the present invention should not be limited by any of the above described exemplary embodiments, but should be defined only in accordance with the following claims and their equivalents.

What is claimed is:

1. A method of reducing power dissipation while testing an integrated circuits using a sequential scan technique, said integrated circuit being operable in a functional mode or a scan mode according to said sequential scan technique, said integrated circuit comprising a sequential element providing an output to a combinatorial logic in said functional mode, said method comprising:
isolating said output from said combinatorial logic in said scan mode.

2. The method of claim 1, further comprising providing said output to a subsequent sequential element in a scan chain in said scan mode, wherein said scan chain comprises a plurality of sequential elements connected in series in said scan mode, said plurality of sequential elements comprising said sequential element and said subsequent sequential element.

3. The method of claim 2, wherein said isolating comprises providing an AND gate receiving an indication of whether said integrated circuit is operating in scan mode of sequential mode as one input and said output as another input.

4. A power reduction circuit for reducing power dissipation while testing an integrated circuits using a sequential scan technique, said integrated circuit being operable in a functional mode or a scan mode according to said sequential scan technique, said integrated circuit comprising a sequential element providing an output to a combinatorial logic in said functional mode, said power reduction circuit comprising:
means for isolating said output from said combinatorial logic in said scan mode.

5. The power reduction circuit of claim 4, further comprising means for providing said output to a subsequent sequential element in a scan chain in said scan mode, wherein said scan chain comprises a plurality of sequential elements connected in series in said scan mode, said plurality of sequential elements comprising said sequential element and said subsequent sequential element.

6. The power reduction circuit of claim 5, wherein said means for isolating comprises an AND gate receiving an indication of whether said integrated circuit is operating in scan mode of sequential mode as one input and said output as another input.

7. A scan cell suitable for testing according to a sequential scan technique, said scan cell being designed for inclusion in an integrated circuit, said integrated circuit being operable in a functional mode or a scan mode according to said sequential scan technique, said scan cell comprising:
a multiplexer selectively forwarding a functional input or a scan input on a multiplexer output path according to an indication of whether said scan cell is operating in said functional mode or said scan mode respectively;
a sequential element having a data input coupled to said multiplexer output path and generating a sequential output; and
a first data path providing said sequential output only when said indication indicates that said scan cell is operating in said functional mode,
wherein said first data path is coupled to a functional portion of said integrated circuit.

8. The scan cell of claim 7, further comprising a second data path providing said sequential output to a next scan cell in said scan chain.

9. The scan cell of claim 8, wherein said sequential element comprises a flip-flop.
